(19) United States
(12) Patent Application Publication
(10) Pub. No.: US 2015/0349147 A1
(43) Pub. Date: Dec. 3, 2015

(54) Broad Band Anti-Reflection Coating for Photovoltaic Devices and Other Devices

(71) Applicant: Raydex Technology, Inc., Lexington, MA (US)

(72) Inventors: Jingqun Xi, Lexington, MA (US); Frank W. Mont, Troy, NY (US)

(73) Assignee: Raydex Technology, Inc., Lexington, MA (US)

(21) Appl. No.: 14/104,399

(22) Filed: Dec. 12, 2013

Related U.S. Application Data
(60) Provisional application No. 61/737,101, filed on Dec. 14, 2012.

(51) Int. Cl. H01L 31/0216; H01L 31/0735; H01L 31/0687; H01L 31/0725; H01L 31/048; H01L 31/0304

(52) U.S. Cl. CPC H01L 31/02168; H01L 31/0481; H01L 31/03046; H01L 31/06875; H01L 31/0725; H01L 31/0735

(57) ABSTRACT

A device having a broad-band, white incident angle range anti-reflection coating disclosed. The device includes a substrate having a first refractive index, at least one interference layer disposed on top of the substrate; and a gradient index optical layer. The gradient index optical layer has a gradient refractive index disposed on top of the at least one high index optical layer. The gradient index optical layer has a bottom refractive index at a bottom surface of the gradient index optical layer and a top refractive index at a top surface of the gradient index optical layer. The gradient refractive index of the gradient index optical layer decreases gradually from the bottom surface to the top surface. The at least one interference layer has a refractive index between the first refractive index of the substrate and the bottom refractive index of the gradient index optical layer.

### CROSS REFERENCE TO RELATED APPLICATIONS

This claims priority to provisional U.S. patent application Ser. No. 61/737,101, filed Dec. 14, 2012, the entirety of which is incorporated herein by this reference thereto.

### GOVERNMENT LICENSE RIGHTS

This invention was made with government support contract number FA9453-12-M-0355 awarded by Air Force Research Laboratory. The Government has certain rights in the invention.

### FIELD OF THE INVENTION

The invention relates to anti-reflection coating. More particularly, the invention concerns a device comprising board band anti-reflection coating for photovoltaic devices and other devices.

### BACKGROUND

A photovoltaic device is made of a high index semiconductor material. Therefore, it has strong surface reflections. Although a photovoltaic device is usually encapsulated using an encapsulant, the index contrast between photovoltaic device surface index and encapsulant index is still very high, therefore, the surface reflection is also still very high.

### BRIEF DESCRIPTION OF THE DRAWINGS

FIG. 1 is schematic drawing of cross-section view for a photovoltaic cell with anti-reflection coating on the photovoltaic device

FIG. 2 is schematic drawing of the anti-reflection coating consisting of gradient or graded index layer and a high index layer.

FIG. 3 illustrates an index profile of an anti-reflection coating consisting of high index layer and gradient index layer.

FIG. 4 illustrates a spectral reflectivity of anti-reflection coatings.

FIG. 5 illustrates an index profile consisting of a high index layer and a gradient index layer.

FIG. 6 illustrates an index profile of an anti-reflection coating consisting of a high index layer and a graded index layer.

FIG. 7A illustrates an index profile of an anti-reflection coating consisting of two high index layers and a gradient index layer.

FIG. 7B illustrates an index profile of an anti-reflection coating consisting of an effective graded index layer using a stack of multiple discrete layers.

FIG. 8 illustrates a glass window without anti-reflection coating.

FIG. 9 illustrates a glass window with an anti-reflection coating on the top.

### DETAILED DESCRIPTION

The nature, objectives, and advantages of the invention will become more apparent to those skilled in the art after considering the following detailed description in connection with the accompanying drawings.

A new design and the fabrication method to make broad-band photovoltaic cells with minimized surface reflection at the photovoltaic device surface is disclosed herein. Photovoltaic cells are widely used to convert solar energy to electricity directly. Usually photovoltaic cells suffer from optical surface reflection loss at the photovoltaic device surface due to its high refractive index.

One-layer coating or a two-layer coating, have been developed on the surface of photovoltaic devices to reduce and even eliminate some surface reflections from the photovoltaic device. However, traditional anti-reflection coating technologies can only reduce or eliminate surface reflection within a narrow spectral range and within a narrow incident angle range. These traditional anti-reflection (“AR”) coating technologies cannot work well for broad-band photovoltaic devices, which require an anti-reflection coating with a broad band-width, such as the wavelength range from 300 nm to 1800 nm, and a wide incident angle range, for example, 0° to beyond 45°. Although broad-band, wide incident angle anti-reflection coatings with gradient index profiles have been designed theoretically, there is no practical solution for photovoltaic devices due to the fact that photovoltaic devices have very high refractive index values and there are no optical materials available to achieve such a transparent gradient index profile. “Moth-eye” structures have been demonstrated to mimic the gradient index profile to achieve broad-band anti-reflection. However, moth-eye structures require etching which will damage the photovoltaic device surface. Additionally, its nano-structure generated from the etching process is not mechanically robust enough to survive the encapsulating process. As a result, “moth-eye” structures cannot be used as broad-band anti-reflection coatings on photovoltaic device surfaces.

A manufacturing method and innovative anti-reflection coating solution between photovoltaic device surface and encapsulant is disclosed to achieve broad-band anti-reflection with a wide incident angle range is disclosed herein. Such anti-reflection coating can achieve low reflectivity (<5%) over the wavelength range from 300 nm to 1800 nm and incident angle range from 0° to beyond 45°. The photovoltaic cell structure with such an anti-reflection coating is also disclosed.

The structure and the fabrication method can realize a photovoltaic cell with a broad-band, wide incident angle range anti-reflection coating on the photovoltaic device surface is revealed. The anti-reflection coating on the photovoltaic device can have a surface reflection less than 5% over the wavelength range from 300 nm to 1800 nm and incident angle range from 0° to 45°. The low reflectivity with broad spectral band and wide incident angle range is achieved by combining a gradient index profile and a thin film interference effect in the anti-reflection coating.

Such device can achieve low reflectivity over wide spectral range, e.g., from near UV to near IR; low reflectivity over wide incident angle, e.g., from 0° to over 45°. Such device can be compatible with current PV cell manufacturing process. The AR coating design on photovoltaic can be applied to substrate with high index. The AR performance exceeds other technologies/approaches existing on the market.

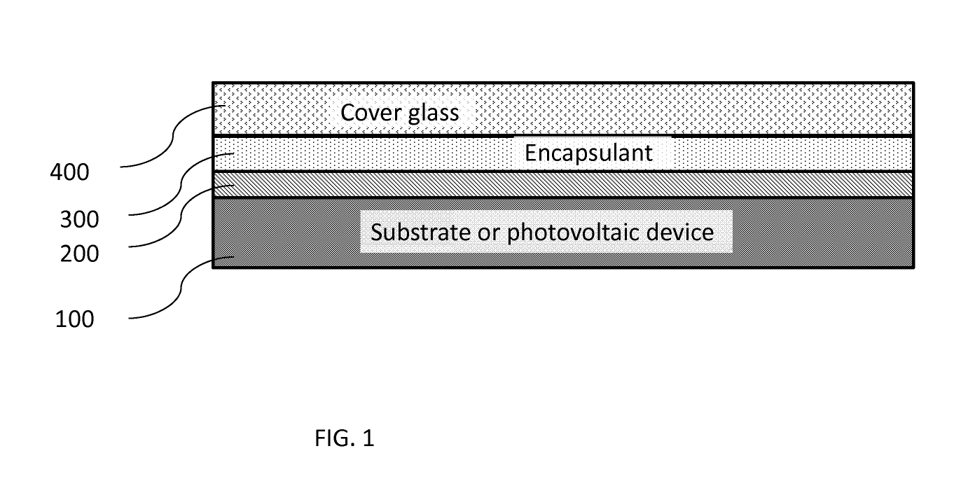

A photovoltaic cell with low optical reflection loss can use a broad-band anti-reflection coating on the photovoltaic device surface. Surface reflection (Fresnel reflection) is caused by the refractive index contrast at the interface between two materials. Its reflectivity at normal incidence can be calculated by Eq. 1

$$R = {\vert \frac{{n}_{sub} - {n}_{amb}}{{n}_{sub} + {n}_{amb}} \vert}^{2} \qquad ( 1 )$$

where n_{amb} and n_{sub} is the refractive index of the ambient and substrate, respectively. Eq. 1 shows that large refractive index contrasts result in high reflectivities. The photovoltaic device is a semiconductor device made of semiconductor materials, such as but not limited to, GaP, GaInP, AlInP, GaAs, Si, Ge, CdS, etc. It has a high refractive index at the top surface. For example, broad-band inverted metamorphic multi-junction (IMM) photovoltaic devices usually have AlInP as the top layer, which has a refractive index >3. The encapsulant, such as, but not limited to, silicone encapsulant, usually has refractive index value of about 1.5 to 1.4. Therefore, there is a huge index contrast between the photovoltaic device surface and the encapsulant. As a result, the photovoltaic device surface reflection has high reflectivity. An anti-reflection coating is usually coated on the surface of the photovoltaic devices to eliminate or reduce its surface reflection. A schematic structure of a photovoltaic cell is shown in FIG. 1. A photovoltaic device 100 is coated with an anti-reflection coating 200 on the top surface of the device 100. The encapsulant 300 is used to encapsulate the whole photovoltaic device 100 with the anti-reflection coating 200, and to attach the cover glass 400 onto the anti-reflection coating 200. The anti-reflection coating 200 reduces or eliminates the surface reflection between photovoltaic device's top surface, and the encapsulant, which has a large index contrast. The refractive index of the encapsulant 300 and the cover glass 400 is usually very close to each other, therefore there is minimal reflection loss at the encapsulant 300 and glass 400 interface, however, one or more anti-reflection coating layers can be applied between encapsulant 300 and glass 400 if needed. An anti-reflection coating can also be coated on top of the cover glass 400 to reduce or eliminate the surface reflection at cover glass 400 surface since the cover glass has an index contrast with its ambient, such as air.

Following Eq. 1, a coating with a gradual or gradient refractive index change from substrate's index, n_{sub}, to ambient index, n_{amb} can eliminate the index contract and the surface reflection. Such an anti-reflection coating can eliminate the surface reflection over a broad spectral range and over a wide incident angle range, which is desired by broad-band photovoltaic devices. However, photovoltaic devices usually have such a high index that no transparent optical material is available to form a coating with a gradient or gradual index change. For example, the current broad-band IMM photovoltaic devices have a GaInP sub-cell and a AlInP window layer on top, both of which have refractive index >3.0. At near ultra-violet spectrum, both GaInP sub-cell and AlInP window layer have index value >4.0, which is much larger than conventional transparent optical material index values. As a result, there are no conventional transparent optical materials available to smoothly eliminate the index contrast between GaInP or AlInP and their ambient, the silicone adhesive with a cover glass. Note, the material selected for an anti-reflection coating should be transparent or have low absorption in the interested spectral range to avoid absorption loss

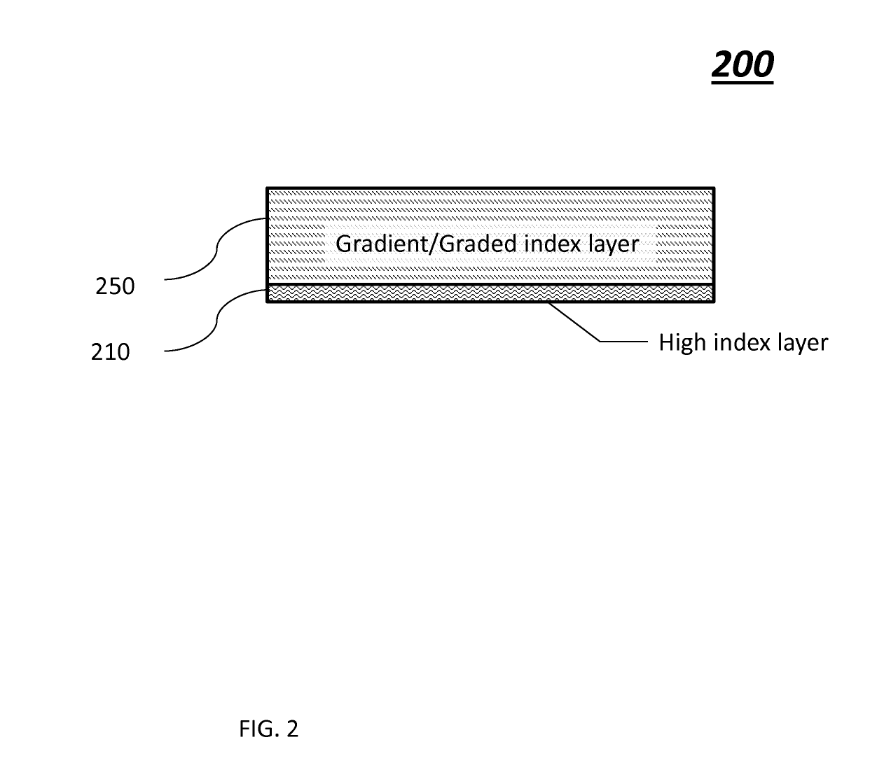

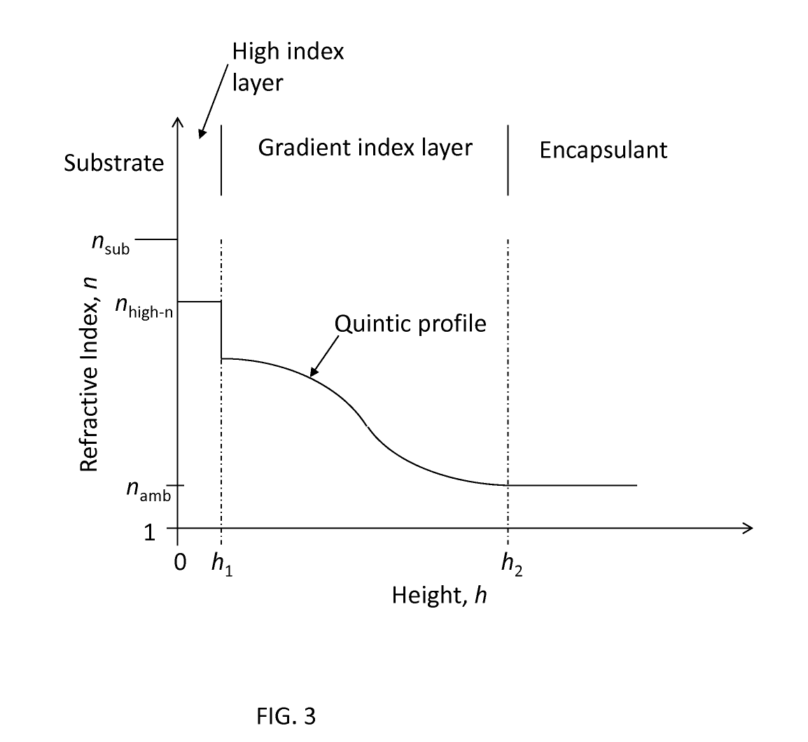

A thin-film based anti-reflection coating design placed between the top surface of the photovoltaic device and the encapsulant can achieve low reflectivity, over a broad spectral range, such as the 300 nm to 1800 nm wavelength range. The anti-reflection coating 200 consists of two components as shown in FIG. 2, thin high index layer 210 and gradient or graded index layer 250, as shown in FIG. 2. Gradient index layer refers to a layer with index changing continuously and smoothly. Graded index layer refers to a layer with index changing continuously but discretely. The index profile of one example of such anti-reflection coating is shown in FIG. 3. The refractive index of high index layer 210 should be a value between the index of substrate 100 from FIG. 1 and the high index value of the gradient index layer 250. The thickness of the high index layer 210 should be chosen to minimize the reflectivity at the short wavelength range, such as a quarter wavelength thickness for the short wavelength range. The gradient index layer 250 should have a proper index profile, such as quintic index profile or linear index profile, to smoothen the index change. The low index value of this gradient index layer 250 should be chosen to be a value that is close to or matched to the index of the coating's ambient, such as encapsulant. The high index value of this gradient index layer 250 should be chosen to be as close as possible to the index value of the photovoltaic device's top surface. Due to the limitation of available high index transparent optical materials, the high index value of the gradient index layer 250 is usually much lower than the index of photovoltaic device top surface. The selection of the high index layer 210 and gradient/graded index layer 250 is highly dependent on the photovoltaic device 100. For example, an IMM triple junction photovoltaic device can have a Ga_{0.5}In_{0.5}P top subcell. The refractive index of the device's top layer is larger than 3.0, and even larger than 4.0 in the near ultra-violet spectrum. A thin high-index material, such as 30 nm TiO₂, can be deposited as a high index layer 210 to minimize the reflection in the near UV spectrum between 300 nm to 400 nm using an interference effect.

A gradient-index layer with a quintic profile, such as a ZrO₂—SiO₂ composite layer, can be deposited on top of the high-index layer to reduce the surface reflection between photovoltaic device and the encapsulant adhesive. The gradient layer must be thick enough to achieve a broad band-width (preferably 500 nm or larger to reduce reflectivity over the broad spectral range from 300 nm to 1800 nm), therefore, only highly transparent materials throughout the solar spectrum can be used. The gradient layer is graded from ZrO₂ down to SiO₂ to index match the index of encapsulant, such as Dow Corning's 93-500 silicone adhesive, and the cerium doped cover glass.

ZrO₂ has the highest refractive index among the viable optical thin film materials that are transparent from 300 nm to 1800 nm. Therefore, a gradient-index ZrO₂—SiO₂ composite layer can be used to eliminate index contrast between ZrO₂ (n≈2.2 and encapsulant/cover glass (n≈1.5). The quintic profile is theoretical the ideal gradient refractive index profile for eliminating surface reflections. The gradient layer will effectively reduce surface reflection at long wavelengths (450 nm to beyond 1800 nm). However, at near UV, there is still a huge index gap between ZrO₂ and GaInP/AlInP, which can cause significant surface reflection at the near UV. To reduce the reflection loss at the near UV, a thin high-index layer can be inserted between the ZrO₂—SiO₂ composite layer and the PV cell to minimize the reflection at the near UV using an interference effect. TiO₂ has the highest refractive index among the transparent optical thin film. But it is not chosen for the gradient-index composite layer fabrication because it is absorbing below 400 nm. However, TiO₂ can be used for this thin high-index layer between the gradient-index ZrO₂—SiO₂ layer and the PV cell. The thin high-refractive index layer will reduce spectral reflectance for short wavelengths (between 300 nm to 450 nm). Due to TiO₂'s small thickness, the absorption losses for wavelengths below 400 nm will be minimized, therefore, TiO₂ is still acceptable as the high-index layer.

The selection criteria for the thin high-index layer on PV cell as shown in FIG. 2 can be described assuming a quarter-wavelength thick single layer, AR coating formula as follows:

n_{high-n}=\sqrt{n_{sub}n_{amb}} (2)

where n_{high-n}, n_{sub}, and nₐₘₚ are the refractive index value of the high-index layer, substrate, and surrounding ambient material, respectively. To minimize reflections at 350 nm for a material between a GaInP substrate (nₛ≈4.2 @ 350 nm) and a ZrO—SiO₂ gradient (ambient of ZrO₂, n_{ambient}≈2.35 @ 350 nm), the perfect material would be n_{high-n}=3.14 @ 350 nm. TiO₂ (n_{TiO2}≈2.8 @ 350 nm) (measured and deposited by inventor) and ZnS (n_{ZnS}≈2.8 @ 350 nm) have refractive index values close to this ideal n_{high-n}. Therefore, they can be chosen for this high index layer. The ideal quarter-wave thickness for TiO₂ and ZnS is 31.5 nm. Therefore, a TiO₂ or ZnS with a thickness close to 30 nm can be used in this anti-reflection coating. Ideally, a high-index thin film with no or low absorption over the whole interested spectrum, from 300 nm to 1800 nm, is preferred. Other candidates include SiC or AlP. In practice, optical material with low absorption or absorption in the near ultra-violet spectrum, such as TiO₂ or ZnS, can also be used as high index layer 210.

The combination of high index layer 210 and gradient index layer 250 can achieve low reflectivity over the whole spectral range from the ultra-violet to near infrared spectra. The gradient-index layer 250 can also be other material systems as long as it can provide high index value at the side next to the high index layer 210, and index match to the ambient at the side next to the ambient, such as encapsulant. For example, a Si₃N₄—SiO₂ or SiON gradient index layer can be used as gradient index layer 210 in this anti-reflection coating design due to the fact that Si₃N₄'s refractive index is also high (n≈2).

The gradient index layer 250 can be deposited using a co-sputtering process or other deposition processes that can deposition two or multiple materials together to engineer the index profile of the coating. For example, ZrO₂—SiO₂ composite layer can be deposited using co-sputtering process. This co-sputtering process is the simultaneous deposition of ZrO₂ and SiO₂ that generates a composite or “mixed” material with a refractive index value between the index of ZrO₂ and SiO₂. By adjusting the deposition rate of ZrO₂ and SiO₂ independently during the co-sputtering process, ZrO₂—SiO₂ composite layers with any refractive index between ZrO₂ and SiO₂ can be achieved. For example, assuming a linear relationship, the refractive index of ZrO₂—SiO₂ composite material, n_{ZrO2-SiO2}, can be calculated using the following formula

n_{ZrO2-SiO2}=n_{ZrO2}x+n_{SiO2}(1−x) (3)

x is the ZrO₂ compositional fraction with n_{ZrO2}≈2.35 and n_{SiO2}≈1.45. In the sputtering process, the deposition rate of ZrO₂ and SiO₂ is controlled properly so that a final gradient index ZrO₂—SiO₂ composite layer with desired index profile can be achieved. Other deposition processes can also be used to deposit gradient index layer, as long as it can mix multiple material together or has the tunability to adjust the composition or index profile of the gradient index layer. Other deposition processes are, but not limited to, thermal evaporation that thermally evaporate two or multiple material simultaneously, electron beam evaporation that evaporate two or multiple material simultaneously using e-beam evaporator, molecular beam epitaxy, chemical vapor deposition, etc. The gradient index layer can also be a composite layer consisting of more than two materials.

For example, two method may be used for gradient index deposition. The first is the co-deposition process, which can be co-sputtering, co-evaporation, and any other co-deposition process. The second is to use a stack of engineered multiple layers with each layer having very small thickness, such as <50 nm. The effective refractive index of the stacked multiple layers can form a gradient index profile as designed.

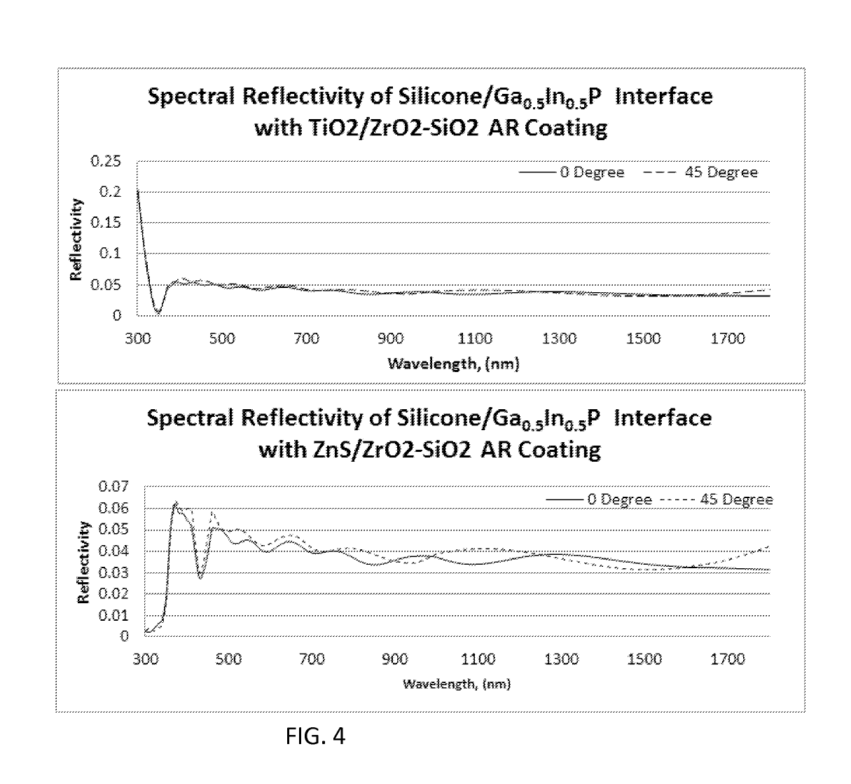

FIG. 4 shows spectral reflectivity simulation results for AR coatings placed at the interface between silicone encapsulant and photovoltaic device with Ga_{0.5}In_{0.5}P as the top layer. The anti-reflection coating consists of a thin TiO₂ layer and a gradient index ZrO₂—SiO₂ layer that is deposited on the Ga_{0.5}In_{0.5}P layer. The thickness of TiO₂ is 30 nm, the thickness of ZrO₂—SiO₂ gradient index layer is 1000 nm. The simulated structure from bottom to top is the following: Ga_{0.5}In_{0.5}P/TiO₂/ZrO₂—SiO₂/silicone The ZrO₂—SiO₂ gradient index layer has a quintic index profile, as the following:

$$n ( x ) = {n}_{h} + ( {n}_{1} - {n}_{h} ) \cdot [ 10 \cdot {( \frac{x}{H} )}^{3} - 15 \cdot {( \frac{x}{H} )}^{4} + 6 \cdot {( \frac{x}{H} )}^{5} ] \qquad ( 4 )$$

nₕ is the index at the end with higher index value, which should be n_{ZrO2}. nₗ is the index at the end with lower index value, which is n_{SiO2}. H is the total thickness of the gradient index layer. x is the location of the index, n(x), to be calculated, with x=0, n(0)=nₕ=n_{ZrO2}, and x=H, n(H)=nₗ=n_{SiO2}. The simulation shows average reflectivity is below 5% over the spectral range from 330 nm to 1800 nm at normal incident. At 45° incident angle, its average reflectivity is almost the same and below 5% over the whole spectra from 330 nm to 1800 nm.

FIG. 4 also shows a spectral reflectivity simulation result for an AR coating placed at the interface between silicone encapsulant and Ga_{0.5}In_{0.5}P top layer with an anti-reflection coating having the same structure as previously described except the a 30-nm ZnS replaces the 30-nm TiO₂. The result shows the reflectivity over the spectral range from 300 nm to 1800 nm at normal incident angle is about or below 5%. At 45° incident angle, its reflectivity is also about or below 5% over the whole spectra from 300 nm to 1800 nm.

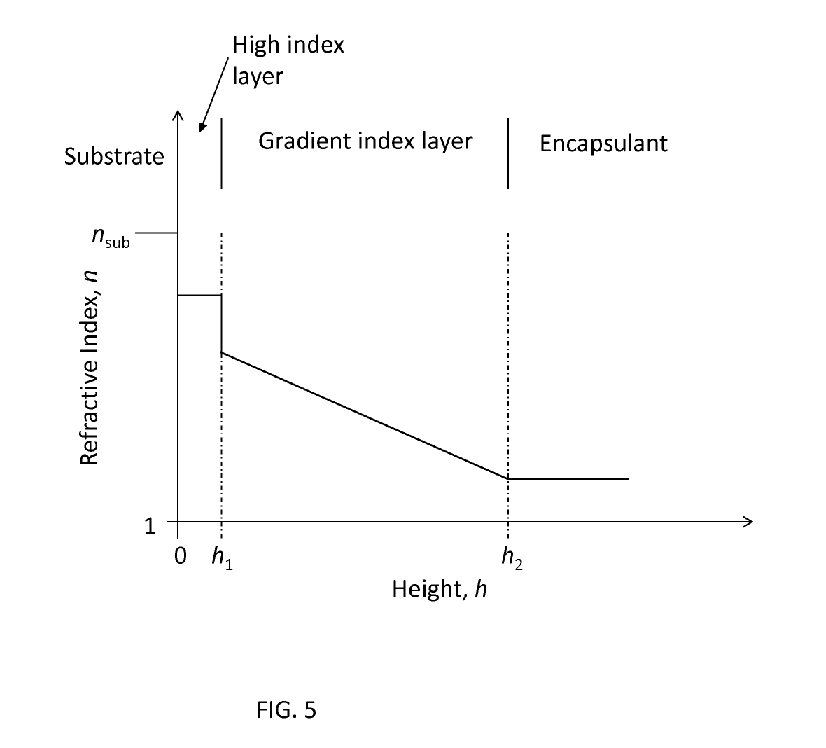

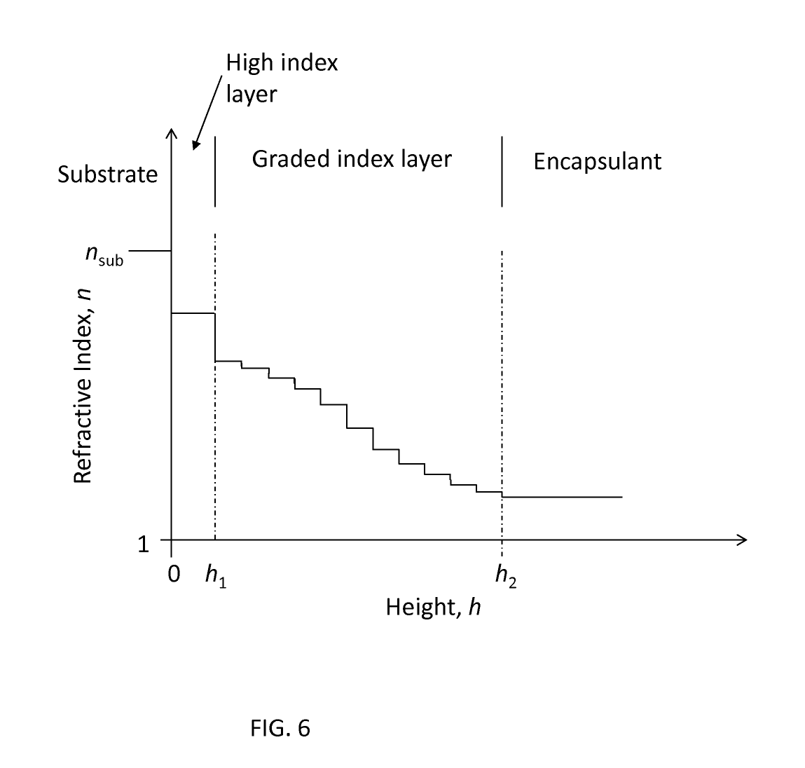

The gradient index layer 250 in FIG. 2 can have any index profile as long as it provides the expected performance regarding surface reflection reduction. For example, in FIG. 3, the index profile of an anti-reflection coating consisting of a high index layer and a gradient index layer with quintic index profile is shown. In FIG. 5, the index profile of an anti-reflection coating consisting of high index layer and a gradient index layer with linear index profile is shown. The gradient index layer in the anti-reflection coating can also be a graded index layer consisting of multiple discrete layers with index profile as shown in FIG. 6.

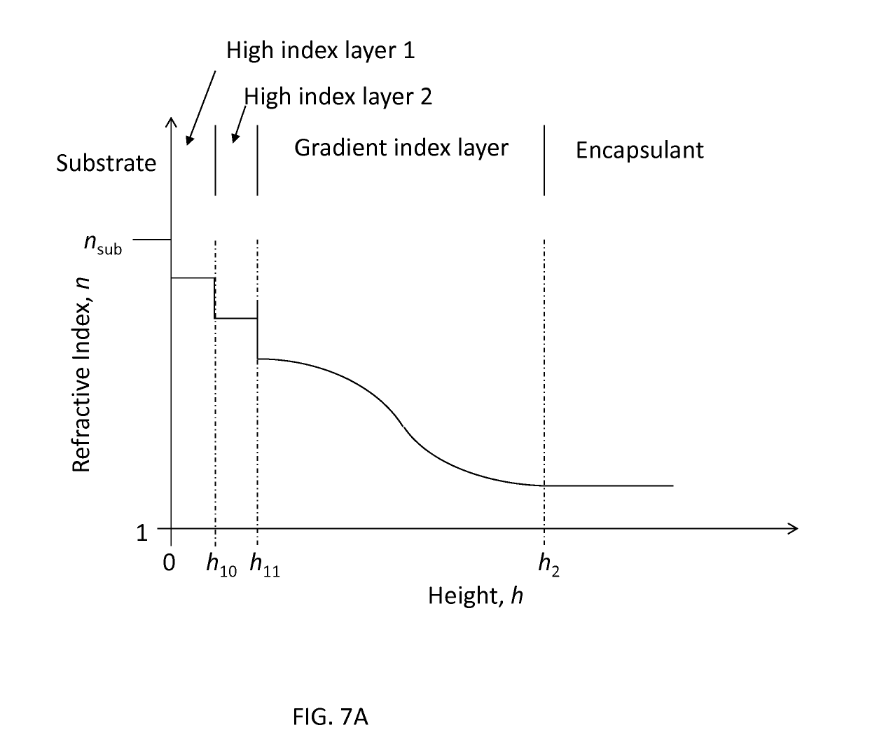

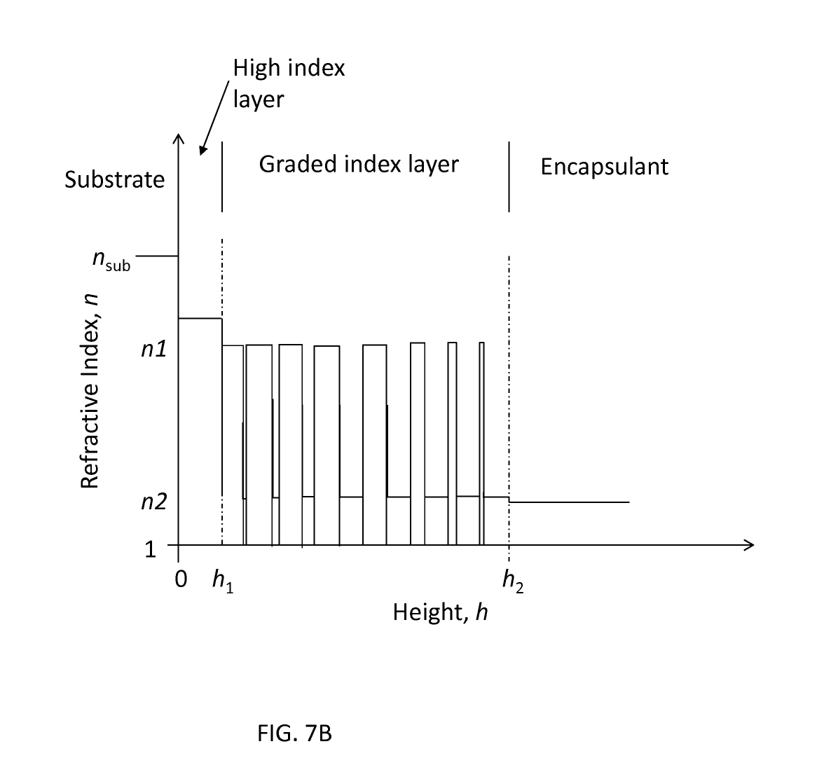

Also, the high index layer in the anti-reflection layer can consist of multiple layers. For example, FIG. 7A shows an anti-reflection coating with 2 high index layers. Both of the high index layers have an index value between the substrate's index and the index of gradient index layer. The high index layer 1 has a higher index value than high index layer 2. The anti-reflection coating can also have more than 2 high index layers in which their index values are between the substrate's index and the index of gradient index layer. Also, the high index layer close to the substrate should have an index value higher than high index layers located further away from the substrate. The high index layers can be fabricated using vapor deposition process, such as but not limited to, atomic layer deposition, chemical vapor deposition, e-beam evaporation, sputtering process, and thermal evaporation. The high index layers can also be fabricated by any other deposition process, as long as it can form an optical thin film with a desired thickness.

The graded index layer can also be achieved using a stack of multiple discrete layers with large index difference. For example, FIG. 7B illustrate an index profile of an anti-reflection coating consisting of an effective graded index layer using the stack of discrete layers from two different materials. Material 1 has index of n1, Material 2 has index of n2. At the top of the high index layer, there is a first Material 1 layer, and first Material 2 layer. The thickness of Material 1 layer is much larger than the thickness of Material 2 layer. As a result, the effective refractive index of first Material 1 layer and first Material 2 layer stacking together should be slightly lower than n1. On top of them, the Material 1 layers thickness become smaller and smaller, while the Material 2 layers thickness become larger and larger. As a result, the effective refractive index of Material 1 and Material 2 layers stacking together become smaller and smaller as the layers away from the substrate. Overall, the stacking of Material 1 layers and Material 2 layers, as shown in FIG. 7B, shows an effective graded index layer, shows index changing from n1 to n2. Such effective graded index layer can also be used as an anti-reflection coating

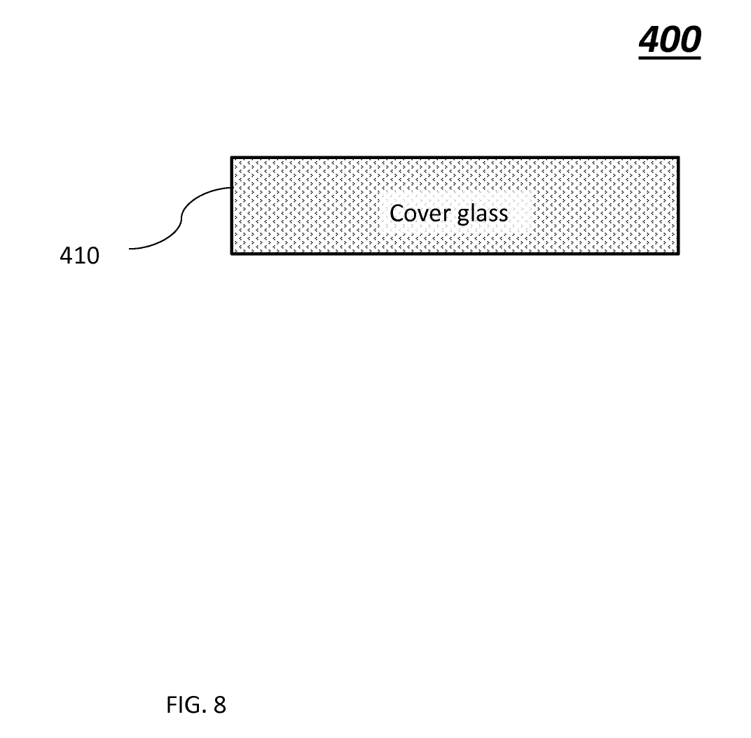

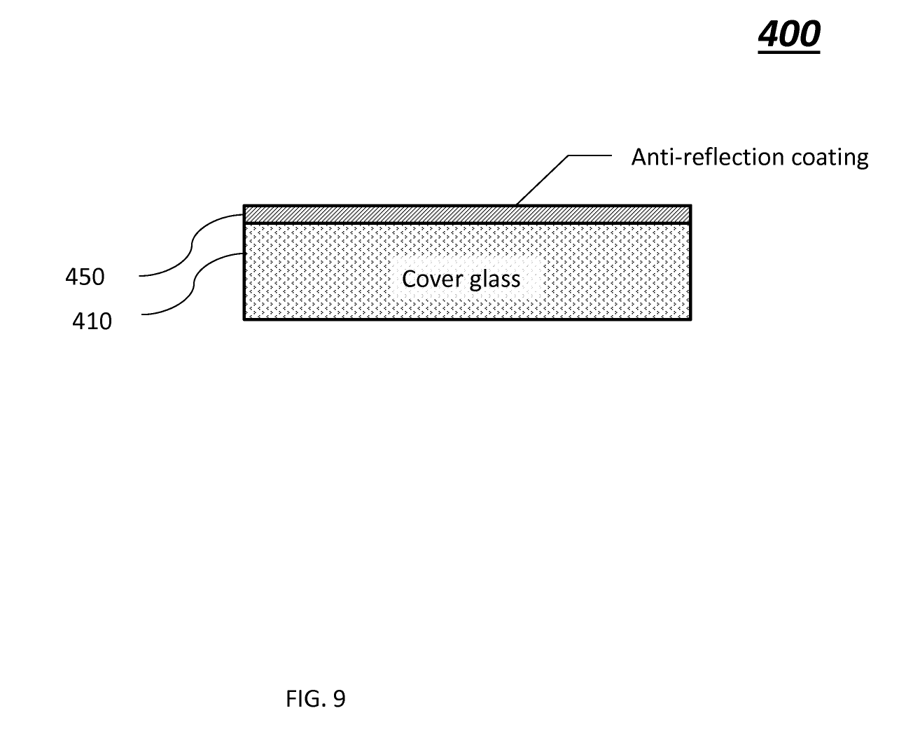

After the anti-reflection coating deposition, the photovoltaic device will be encapsulated using an encapsulant, and a cover glass can be attached to the photovoltaic device using an encapsulant, such as shown in FIG. 1. The cover glass usually is Cr-doped glass. It can also be any other optically transparent optical window. Additionally, the cover glass can have no anti-reflection coating on it, such as shown in FIG. 8, or have an anti-reflection coating on the top surface, such as shown in FIG. 9 to remove or reduce the surface reflection between ambient, such as air, and cover glass itself. Particularly, “moth-eye” structured anti-reflection coating or nano-structured anti-reflection coating can be used as the broad-band anti-reflection coating Therefore, cover glass with “moth-eye” anti-reflection coating or nano-structured anti-reflection coating can be used as a cover glass for broad-band photovoltaic cells. Photovoltaic cells with a broad-band anti-reflection coating on both photovoltaic device and cover glass will have very low surface reflection loss over a broad spectral range and viewing angle

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

Furthermore, although elements of the invention may be described or claimed in the singular, reference to an element in the singular is not intended to mean “one and only one” unless explicitly so stated, but shall mean “one or more”. Additionally, ordinarily skilled artisans will recognize that operational sequences must be set forth in some specific order for the purpose of explanation and claiming, but the present invention contemplates various changes beyond such specific order.

1. A device comprising:
a substrate having a first refractive index;
at least one interference layer disposed on top of the substrate; and
a gradient index optical layer having a gradient refractive index disposed on top of the at least one high index optical layer; wherein the gradient index optical layer has a bottom refractive index at a bottom surface of the gradient index optical layer and a top refractive index at a top surface of the gradient index optical layer, and the gradient refractive index of the gradient index optical layer decreases gradually from the bottom surface to the top surface;
wherein the at least one interference layer has a refractive index between the first refractive index of the substrate and the bottom refractive index of the gradient index optical layer.

2. The device of claim 1, wherein the substrate comprises an optoelectronic component or an optical component.

3. The device of claim 1, wherein the substrate comprises a photovoltaic cell or a light emitting diode.

4. The device of claim 1, wherein the at least one interference layer comprises a first layer on top of the substrate and a second layer on top of the first layer, a refractive index of the first layer is between the first refractive index of the substrate and a refractive index of the second layer, and a refractive index of the second layer is between a refractive index of the first layer and the bottom refractive index of the gradient index optical layer.

5. The device of claim 1, further comprising:
an encapsulant on top of the gradient index optical layer;
wherein the top refractive index of the gradient index optical layer is close to a refractive index of the encapsulant such that the at least one interference layer and the gradient index optical layer smooth out an index change between the substrate and the encapsulant.

6. The device of claim 1, wherein a thickness of the at least one interference layer is such that the reflectivity of the at least one interference layer is minimized at a short wavelength range of a broad spectral range of the device.

7. The device of claim 1, wherein a thickness of the at least one interference layer is one quarter of a short wavelength of a broad spectral range of the device so that the reflectivity of the at least one interference layer is minimized.

8. The device of claim 1, wherein the gradient index optical layer has a quintic index profile or a linear index profile.

9. The device of claim 1, wherein the gradient index optical layer comprises multiple layers with graded refractive indices matching a index profile of the gradient index optical layer.

10. The device of claim 1, wherein a thickness of the gradient index optical layer is such that the gradient index optical layer achieves a broad bandwidth from 300 nm to 1800 nm.

11. A photovoltaic device comprising:
a photovoltaic cell having a first refractive index;
at least one interference layer disposed on top of the photovoltaic cell; and
a gradient index optical layer having a gradient refractive index disposed on top of the at least one high index optical layer; wherein the gradient index optical layer has a bottom refractive index at a bottom surface of the gradient index optical layer and a top refractive index at a top surface of the gradient index optical layer, the gradient refractive index of the gradient index optical layer decreases gradually from the bottom surface to the top surface;
wherein the at least one interference layer has a refractive index between the first refractive index of the photovoltaic cell and the bottom refractive index of the gradient index optical layer.

12. The photovoltaic device of claim 11, wherein the gradient index optical layer comprises two light-transmissive materials.

13. The photovoltaic device of claim 11, wherein the gradient index optical layer comprises two or more light-transmissive materials that are deposited using a co-deposition process which adjusts deposition rates of the two light-transmissive materials independently during the co-deposition process.

14. The photovoltaic device of claim 11, wherein the gradient index optical layer comprises multiple sublayers, and the refractive indices of the sublayers are specified by an index profile of the gradient index optical layer.

15. The photovoltaic device of claim 13, wherein the two light-transmissive materials are ZrO₂ and SiO₂, and the deposition rates are adjusted according to an index profile of the gradient index optical layer.

16. The photovoltaic device of claim 13, wherein the two light-transmissive materials are TiO₂ and SiO₂, and the deposition rates are adjusted according to an index profile of the gradient index optical layer.

17. The photovoltaic device of claim 13, wherein the light-transmissive materials comprises at least three materials including TiO₂, ZrO₂, SiO₂, MgF₂, Al₂O₃, HfO₂, or Ta₂O₅, and the deposition rates for each of the at least three materials are adjusted according to an index profile of the gradient index optical layer.

18. The photovoltaic device of claim 11, wherein the photovoltaic device has a broad bandwidth from a short wavelength to a long wavelength.

19. The photovoltaic device of claim 18, wherein the interference layer has a thickness of a quarter of the short wavelength of the broad bandwidth such that reflection of the interference layer is minimized at the short wavelength.

20. The photovoltaic device of claim 11, wherein the top refractive index of the gradient index optical layer is close to a refractive index of ambient air or a refractive index of a encapsulant layer on top of the gradient index optical layer.

21. The photovoltaic device of claim 11, wherein the refractive index of the at least one interference layer and an index profile of the gradient index optical layer is determined such that the photovoltaic device has a reflectivity less than 5% over a wavelength range from 300 nm to 1800 nm and from an incident angle range from zero degree to 45 degree.

22. The photovoltaic device of claim 11, wherein the at least one interference layer comprises a first layer on top of the photovoltaic cell and a second layer on top of the first layer, a refractive index of the first layer is between the first refractive index of the photovoltaic cell and a refractive index of the second layer, and a refractive index of the second layer is between a refractive index of the first layer and the bottom refractive index of the gradient index optical layer.

23. The photovoltaic device of claim 11, further comprising:
an encapsulant on top of the gradient index optical layer;
a cover glass attached to the encapsulant; and
an anti-reflection coating on top of the cover glass.
